(19) United States
(12) Patent Application Publication
(10) Pub. No.: US 2024/0301176 A1
(43) Pub. Date: Sep. 12, 2024

(54) EPOXY RESIN COMPOSITION, ADHESIVE FILM, PRINTED WIRING BOARD, SEMICONDUCTOR CHIP PACKAGE, SEMICONDUCTOR DEVICE, AND METHOD FOR USING ADHESIVE FILM

(71) Applicant: ASAHI KASEI KABUSHIKI KAISHA, Tokyo (JP)

(72) Inventors: Kenzo ONIZUKA, Tokyo (JP); Naoya KAMIMURA, Tokyo (JP); Masanori YOSHIDA, Tokyo (JP)

(73) Assignee: ASAHI KASEI KABUSHIKI KAISHA, Tokyo (JP)

(21) Appl. No.: 18/268,741

(22) PCT Filed: Dec. 14, 2021
(86) PCT No.: PCT/JP2021/046127

§ 371 Date: Jun. 21, 2023

(30) Foreign Application Priority Data
Dec. 22, 2020 (JP) 2020-212769
Jan. 18, 2021 (JP) 2021-005649

(51) Int. Cl. C08K 9/10; C08K 3/013; C08K 5/05; C09J 163/00; H01L 23/498; H05K 3/46

(52) U.S. Cl. CPC C08K 9/10; C08K 3/013; C08K 5/05; C09J 163/00; C08K 2201/003; C08K 2201/006; H01L 23/49894; H05K 3/4661; H05K 2203/068; H05K 2203/107; H05K 2203/1461

(57) ABSTRACT

An epoxy resin composition comprising an epoxy resin (A) and a latent curing agent (B), wherein the latent curing agent (B) is solid at 25° C.

### TECHNICAL FIELD

The present invention relates to an epoxy resin composition, an adhesive film, a printed wiring board, a semiconductor chip package, a semiconductor device, and a method for using the adhesive film.

### BACKGROUND ART

Conventionally, as an adhesive for a semiconductor element or an adhesive for a printed wiring board, a thermosetting resin composition including an epoxy resin having excellent adhesiveness and high reliability or the like has been used. As a constituent component of the thermosetting resin composition, an epoxy resin, a curing agent such as a phenol resin having reactivity with the epoxy resin, and a curing catalyst that accelerates the reaction between the epoxy resin and the curing agent are generally used.

In recent years, the performance of a semiconductor element and a printed wiring board has been improved, and these uses a build-up layer and are multi-layered, and are requested to have finer and higher density wiring and further, a lower dielectric loss tangent. In addition, with the multi-layered packaging of a semiconductor element or a printed wiring board, there is a demand for an adhesive that can be cured under a low temperature condition.

In response to this, various efforts have been made.

For example, Patent Literature 1 discloses an epoxy resin composition for forming an insulating layer of a multi-layer printed wiring board, the epoxy resin composition comprising (A) an epoxy resin, (B) an active ester compound as a curing agent for the epoxy resin, (C) a triazine-containing cresol novolac resin, and (D) an inorganic filler having an average particle diameter of 1 μm or less, wherein when a non-volatile component in the epoxy resin composition is 100% by mass, (D) a content of the inorganic filler having an average particle diameter of 1 μm or less is 48% by mass or more and 85% by mass or less. Patent Literature 1 discloses that the epoxy resin composition exhibits a high close adhesion strength to a plated conductor, and can achieve a lower linear expansion coefficient and a lower dielectric loss tangent of an insulating layer.

In addition, Patent Literature 2 discloses an epoxy resin composition comprising (A) an epoxy resin, (B) a curing agent, and (C) an inorganic filler surface-treated with a specific surface treatment agent, as a resin composition for printed wiring exhibiting a good reflow behavior in a part packaging step even if a printed wiring board is thin.

### CITATION LIST

### Patent Literature

Patent Literature 1: Japanese Patent No. 6190092
Patent Literature 2: Japanese Patent Laid-Open No. 2020-045501

### SUMMARY OF INVENTION

### Technical Problem

However, the epoxy resin compositions disclosed in Patent Literatures 1 and 2 have insufficient storage stability after film formation, poor embeddability of a fine wiring, poor warpage of a substrate since the epoxy resin compositions require a high temperature at the time of curing, and practically insufficient curing performance, and thus have the following problem: there is room for improvement in these properties.

Therefore, an object of the present invention is to provide an epoxy resin composition having good storage stability after film formation, good embeddability of a fine wiring and good warpage of a substrate, and excellent curing performance, and an adhesive film, a printed wiring board, a semiconductor chip package, a semiconductor device, and the like having a resin layer including the epoxy resin composition.

### Solution to Problem

The present inventor has carried out diligent studies in order to solve the above problem, and as a result, found that the above problem can be solved by adopting a latent curing agent (B) satisfying specific conditions in a resin composition containing an epoxy resin (A) and a latent curing agent (B), leading to the completion of the present invention.

That is, the present invention is as follows.

[1]

An epoxy resin composition comprising:
an epoxy resin (A); and
a latent curing agent (B), wherein the latent curing agent (B) is solid at 25° C.
   [2]

The epoxy resin composition according to the above [1], wherein the epoxy resin composition further comprises an alcohol (C) represented by the following formula (1):

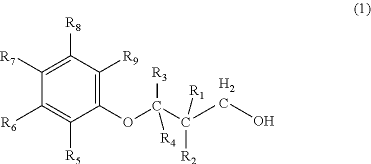

wherein R₁ to R₉ are each independently one selected from the group consisting of a hydrogen atom, a hydroxyl group, an alkyl group, an aromatic group, a substituent including a hetero atom, and a substituent including a halogen atom; R₁ to R₉ are the same or different; and any selected from R₅ to R₉ optionally bonds with each other to form a ring structure, and the ring structure is optionally a ring condensed with a benzene ring shown in the formula.

[3]

The epoxy resin composition according to the above [1] or [2], wherein the latent curing agent (B) is an amine-based curing agent having an amine moiety.

[4]

The epoxy resin composition according to any one of the above [1] to [3], wherein
the latent curing agent (B) has a particle diameter D50 at an undersize fraction of 50% of more than 0.3 μm and 10 μm or less, and
a particle size distribution represented by a ratio (D99/D50) of a particle diameter D99 at an undersize fraction of 99% to the particle diameter D50 at the undersize fraction of 50% of 6 or less.
   [5]

The epoxy resin composition according to any one of the above [1] to [4], wherein
the latent curing agent (B) satisfies a relationship represented by the following expression (2) with a specific surface area value (=Y (m²/g)) and the particle diameter D50 at the undersize fraction of 50% (=X (μm)):

$$4. X - 1 \leq Y \leq 8.3 X - 1 \qquad ( 2 )$$

wherein when the latent curing agent (B) is obtained by encapsulating a curing agent component with an encapsulating agent, the curing agent component before encapsulation satisfies the above expression (2).
[6]

The epoxy resin composition according to any one of the above [1] to [5], wherein
the latent curing agent (B) comprises
a core (c) that is a curing agent component and a shell (s) covering the core (c), and
   wherein the shell (s) comprises at least a bonding group (x) absorbing an infrared radiation having a wave number of 1630 cm⁻¹ or more and 1680 cm⁻¹ or less, a bonding group (y) absorbing an infrared radiation having a wave number of 1680 cm⁻¹ or more and 1725 cm⁻¹ or less, and a bonding group (z) absorbing an infrared radiation having a wave number of 1730 cm⁻¹ or more and 1755 cm⁻¹ or less.
   [7]

The epoxy resin composition according to any one of the above [2] to [6], wherein R₁ in the formula (1) is a hydroxyl group.

[8]

The epoxy resin composition according to any one of the above [2] to [7], wherein
the epoxy resin composition comprises the alcohol (C)
in an amount of 0.001 parts by mass or more and 20 parts by mass or less per 100 parts by mass in total of the epoxy resin (A) and the latent curing agent (B).
   [9]

The epoxy resin composition according to any one of the above [2] to [8], wherein
the epoxy resin composition comprises the alcohol (C)
in an amount of 0.1 parts by mass or more and 20 parts by mass or less per 100 parts by mass in total of the epoxy resin (A) and the latent curing agent (B).
   [10]

The epoxy resin composition according to any one of the above [1] to [9], wherein the epoxy resin composition further comprises one or more curing agents selected from the group consisting of a phenol-based curing agent, an active ester curing agent, an amine-based curing agent, an acid anhydride-based curing agent, and a thiol-based curing agent, other than the latent curing agent (B).

[11]

The epoxy resin composition according to any one of the above [1] to [10], wherein the epoxy resin composition further comprises a film-forming polymer (D).

[12]

The epoxy resin composition according to any one of the above [1] to [11], wherein the epoxy resin composition further comprises a filler (E).

[13]

The epoxy resin composition according to any one of the above [1] to [12], wherein the filler (E) is an inorganic filler.

[14]

The epoxy resin composition according to any one of the above [1] to [13], wherein the epoxy resin composition further comprises an additive (F).

[15]

An adhesive film comprising:
a support; and
a resin layer comprising the epoxy resin composition according to any one of the above [1] to [14] on the support.
   [16]

The adhesive film according to the above [15], wherein the adhesive film has a thickness of 20 μm or less.

[17]

The adhesive film according to the above [15] or [16], wherein the adhesive film is an adhesive film for forming a build-up layer of a printed wiring board.

[18]

The adhesive film according to the above [15] or [16], wherein the adhesive film is an adhesive film for an insulating layer of a semiconductor chip package.

[19]

A printed wiring board comprising a layer obtained by curing the adhesive film according to the above [15] or [16].

[20]

A semiconductor chip package comprising a layer obtained by curing the adhesive film according to the above [15] or [16].

[21]

A semiconductor device comprising the printed wiring board according to the above [19] and/or the semiconductor chip package according to the above [20].

[22]

A method for using the adhesive film according to the above [15] or [16], comprising laminating the adhesive film under a condition of a pressure bonding pressure of 40 MPa or less and then producing a laminated material or a semiconductor chip package under a heating condition of a temperature of 220° C. or less.

### Advantageous Effect of Invention

According to the present invention, an epoxy resin composition having good storage stability after film formation, excellent embeddability of a fine wiring and excellent curing performance, and capable of achieving both storage stability and reactivity can be obtained.

### DESCRIPTION OF EMBODIMENT

Hereinafter, an embodiment of the present invention (hereinafter, also simply referred to as “the present embodiment”) will be described in detail.

The present embodiment is an example for describing the present invention, and the present invention is not limited only to the present embodiment. That is, various modifications can be made to the present invention as long as they do not depart from the scope thereof.

As used herein, an expression of a range including the term “to” with numerical values or physical property values provided before and after the term is used to mean that the values before and after the term are included in the range.

### [Epoxy Resin Composition]

The epoxy resin composition of the present embodiment contains:
an epoxy resin (A); and
a latent curing agent (B), wherein
the latent curing agent (B) is solid at 25° C.

By having the above configuration, an epoxy resin composition having good storage stability after film formation, excellent embeddability of a fine wiring and excellent curing performance, and excellent storage stability and reactivity can be obtained.

In addition, by using the epoxy resin composition of the present embodiment, the reliability can be improved in an adhesive film, a printed wiring board, a semiconductor chip package, a semiconductor device, and the like, which are required to have multi-layering, finer and higher density wiring, a lower dielectric loss tangent, or the like.

### (Epoxy Resin (A))

The epoxy resin composition of the present embodiment contains an epoxy resin (A).

The epoxy resin (A) is not particularly limited, and various known ones can be appropriately selected and used.

Epoxy resins (A) may be used singly or in combinations of two or more.

Examples of the epoxy resin (A) include, but are not limited to, a bifunctional epoxy resin such as a bisphenol A type epoxy resin, a bisphenol F type epoxy resin, a bisphenol AD type epoxy resin, a bisphenol AF type epoxy resin, a tetrabromobisphenol A type epoxy resin, a biphenyl type epoxy resin, a tetramethylbiphenyl type epoxy resin, a tetrafluorobiphenyl type epoxy resin, a tetrabromobiphenyl type epoxy resin, a diphenyl ether type epoxy resin, a benzophenone type epoxy resin, a phenylbenzoate type epoxy resin, a diphenyl sulfide type epoxy resin, a diphenyl sulfoxide type epoxy resin, a diphenylsulfone type epoxy resin, a diphenyl disulfide type epoxy resin, a naphthalene type epoxy resin, an anthracene type epoxy resin, a hydroquinone type epoxy resin, a methylhydroquinone type epoxy resin, a dibutylhydroquinone type epoxy resin, a resorcin type epoxy resin, a methylresorcin type epoxy resin, a catechol type epoxy resin, or an N, N-diglycidylaniline type epoxy resin.

In addition, examples of the epoxy resin (A) include a trifunctional epoxy resin such as an N, N-diglycidylaminobenzene type epoxy resin, an o-(N, N-diglycidylamino) toluene type epoxy resin, or a triazine type epoxy resin; a tetrafunctional epoxy resin such as a tetraglycidyldiaminodiphenylmethane type epoxy resin or a diaminobenzene type epoxy resin; and a polyfunctional epoxy resin such as a phenol novolac type epoxy resin, a cresol novolac type epoxy resin, a triphenylmethane type epoxy resin, a tetraphenylethane type epoxy resin, a dicyclopentadiene type epoxy resin, a naphthol aralkyl type epoxy resin, or a brominated phenol novolac type epoxy resin.

Further, examples of the epoxy resin (A) include a diepoxy resin such as (poly)ethylene glycol diglycidyl ether, (poly) propylene glycol diglycidyl ether, butanediol diglycidyl ether, neopentyl glycol diglycidyl ether, 1,6-hexanediol diglycidyl ether, trimethylolpropane diglycidyl ether, polytetramethylene ether glycol diglycidyl ether, glycerin diglycidyl ether, neopentyl glycol diglycidyl ether, cyclohexane type diglycidyl ether, or dicyclopentadiene type diglycidyl ether; and a triepoxy resin such as trimethylolpropane triglycidyl ether or glycerin triglycidyl ether.

Further examples of the epoxy resin (A) include an alicyclic epoxy resin such as vinyl (3,4-cyclohexene)dioxide or 2-(3,4-epoxycyclohexyl)-5,1-spiro-(3,4-epoxycyclohexyl)-m-dioxane; a hydantoin type epoxy resin such as 1,3-diglycidyl-5-methyl-5-ethylhydantoin; and an epoxy resin having a silicone skeleton such as 1,3-bis(3-glycidoxypropyl)-1,1,3,3-tetramethyldisiloxane.

Still further examples of the epoxy resin (A) include various epoxy resins that can also be used as a reactive diluent such as 2-ethylhexyl glycidyl ether, cyclohexanedimethanol diglycidyl ether, neopentyl glycol diglycidyl ether, 1,6-hexanediol diglycidyl ether, ethylene glycol diglycidyl ether, a hydrogenated bisphenol A type epoxy resin, a silicone modified epoxy resin, (poly)ethylene glycol diglycidyl ether, (poly) propylene glycol diglycidyl ether, butanediol diglycidyl ether, trimethylolpropane diglycidyl ether, polytetramethylene ether glycol diglycidyl ether, glycerin diglycidyl ether, neopentyl glycol diglycidyl ether, cyclohexane type diglycidyl ether, dicyclopentadiene type diglycidyl ether, trimethylolpropane triglycidyl ether, glycerin triglycidyl ether, vinyl (3,4-cyclohexene)dioxide, 2-(3,4-epoxycyclohexyl)-5,1-spiro-(3,4-epoxycyclohexyl)-m-dioxane, a glycidylamine type epoxy resin such as tetraglycidyl bis(aminomethyl)cyclohexane, a 1,3-diglycidyl-5-methyl-5-ethylhydantoin type epoxy resin, a 1,3-bis(3-glycidoxypropyl)-1,1,3,3-tetramethyldisiloxane type epoxy resin, phenylglycidyl ether, cresyl glycidyl ether, p-s-butylphenylglycidyl ether, styrene oxide, p-tert-butylphenylglycidyl ether, o-phenylphenol glycidyl ether, p-phenylphenol glycidyl ether, N-glycidylphthalimide, n-butylglycidyl ether, 2-ethylhexyl glycidyl ether, α-pinene oxide, allyl glycidyl ether, 1-vinyl-3,4-epoxycyclohexane, 1,2-epoxy-4-(2-methyloxiranyl)-1-methylcyclohexane, 1,3-bis(3-glycidoxypropyl)-1,1,3,3-tetramethyldisiloxane, or neodecanoic acid glycidyl ester.

In the epoxy resin composition of the present embodiment, a liquid epoxy resin and a solid epoxy resin can be used in combination as the epoxy resin (A).

When a liquid epoxy resin and a solid epoxy resin are used in combination, the mass ratio thereof (liquid epoxy resin:solid epoxy resin) is not particularly limited, and is preferably in the range of 1:0.1 to 1:6. By setting the mass ratio of a liquid epoxy resin to a solid epoxy resin in the above range, effects including the following effects can be obtained: (i) adequate tackiness can be obtained in an adhesive film having a support and a resin layer wherein the epoxy resin composition of the present embodiment is used for the resin layer, (ii) sufficient flexibility can be obtained and the handleability is improved in the case of use in the form of the adhesive film, and (iii) a cured product having sufficient breaking strength can be obtained.

From the viewpoint of the effects of (i) to (iii) above, the mass ratio of a liquid epoxy resin to a solid epoxy resin (liquid epoxy resin:solid epoxy resin) is more preferably in the range of 1:0.3 to 1:5, and further preferably in the range of 1:0.6 to 1:4.

The content of the epoxy resin (A) in the epoxy resin composition of the present embodiment can be appropriately set according to the desired performance of the epoxy resin of the present embodiment and is not particularly limited, and is preferably 2.5% by mass or more, more preferably 5% by mass or more, and further preferably 10% by mass or more from the viewpoint of curability. In addition, the content thereof is preferably 99% by mass or less, more preferably 95% by mass or less, and further preferably 90% by mass or less from the viewpoint of a film formation property.

### (Latent Curing Agent (B))

The epoxy resin composition of the present embodiment contains a latent curing agent (B).

The latent curing agent (B) is solid at normal temperature (25° C.).

When the epoxy resin composition of the present embodiment includes the latent curing agent (B) that is solid at normal temperature (25° C.), the stability at room temperature is improved and the reactivity with the epoxy resin (A) is improved. In addition, when a further curing agent other than the latent curing agent (B) is used in combination, the latent curing agent can serve as a curing catalyst, and thus is preferable.

As the latent curing agent (B) that is solid at normal temperature (25° C.), an amine-based curing agent having an amine moiety is preferable.

The “amine moiety” is an organic derivative of ammonia and is a functional group that behaves as a base.

By using an amine-based curing agent having an amine moiety as the latent curing agent (B), the following effect can be exerted: high reactivity can be obtained at a predetermined temperature.

Examples of the latent curing agent (B) include, but are not limited to, an imidazole, an imidazole-based adduct, an amine adduct, and encapsulated products thereof.

Specific examples thereof include Amicure PN-23J, PN-40J, and MY-24 (manufactured by Ajinomoto Fine-Techno Co., Inc.), and Fujicure FXR-1020 and FXR-1030 (manufactured by Fuji Chemical Industries Co., Ltd.).

Latent curing agents (B) may be used singly or in combinations of two or more.

Further, the latent curing agent (B) is composed of a particle having a particle diameter D50 at an undersize fraction of 50% of preferably more than 0.3 μm and 10 μm or less, more preferably 1 μm or more and 8 μm or less, and further preferably 1.5 μm or more and 5 μm or less, from the viewpoint of obtaining a homogeneous cured product of the epoxy resin composition of the present embodiment and the viewpoint of ensuring a good physical property of a cured product of the epoxy resin composition by preventing particles of the latent curing agent (B) from aggregating with each other. When the particle diameter D50 of the latent curing agent (B) is 10 μm or less, a homogeneous cured product of the epoxy resin composition tends to be able to be obtained, and when the particle diameter D50 is more than 0.3 μm, aggregation between latent curing agents tends to be able to be suppressed, no curing unevenness tends to occur, and the heat resistance of the cured product tends to be improved.

Examples of a method for setting the particle diameter D50 of the latent curing agent (B) to more than 0.3 μm and 10 μm or less include a method involving carrying out mechanical pulverization and a method for carrying out particle growth in a solvent.

In the latent curing agent (B), the particle size distribution expressed as the ratio of the particle diameter D99 at an undersize fraction of 99% to the particle diameter D50 at an undersize fraction of 50% (hereinafter, sometimes simply referred to as “D99/D50”) is preferably 6.0 or less, more preferably 5.5 or less, and further preferably 5.0 or less, from the viewpoint of preventing aggregation of the particles.

When D99/D50 is 6.0 or less, the number of coarse particles in the powder particles of the latent curing agent (B) tends to be small, the generation of an aggregate tends to be suppressed, and impairment of a physical property of a cured product of the epoxy resin composition tends to be suppressed.

A smaller value of D99/D50 means that the distribution of the particle size of the latent curing agent (B) is sharper, and it tends to be easy to obtain a homogeneous cured product of the epoxy resin composition of the present embodiment and to be able to obtain good curing performance.

In addition, when the value of D99/D50 is 6.0 or less, the particle size distribution of the latent curing agent (B) is narrow and it is difficult for a particle having a relatively large particle diameter to exist, and thus when the epoxy resin composition of the present embodiment is formed into a film, the permeability of the film into a predetermined gap tends to be excellent.

In addition, D99/D50 is preferably 1.2 or more.

When D99/D50 is 1.2 or more, the formation of many gaps between the particles of the latent curing agent (B) tends to be suppressed. D99/D50 is more preferably 1.5 or more, further preferably 1.7 or more, and further more preferably 2.0 or more.

D99/D50 of the latent curing agent (B) can be controlled to 6 or less by a classification operation such as removal of a coarse particle or a fine particle.

The latent curing agent (B) may be a single-layer particle, or may be a core-shell type curing agent particle having a core as a curing agent component and a shell covering the core.

The curing agent particle (curing agent component) for an epoxy resin used as the core is referred to as a “curing agent particle (H) for an epoxy resin,” a “curing agent particle (H),” or a “curing agent (H).”

Preferably, the core-shell type curing agent particle as the latent curing agent (B) has a core formed from a curing agent particle (H) for an epoxy resin and the like (hereinafter, also referred to as a “core (c)”) and a shell covering the core (c) (hereinafter, also referred to as a “shell (s)”), and the shell (s) preferably has, at least on the surface thereof, a bonding group absorbing an infrared radiation having a wave number of 1630 cm⁻¹ or more and 1680 cm⁻¹ or less (hereinafter, also referred to as a “bonding group (x)”), a bonding group absorbing an infrared radiation having a wave number of 1680 cm⁻¹ or more and 1725 cm⁻¹ or less (hereinafter, also referred to as “binding group (y)”), and a bonding group absorbing an infrared radiation having a wave number of 1730 cm⁻¹ or more and 1755 cm⁻¹ or less (hereinafter, also referred to as a “bonding group (z)”).

With such a configuration, the aggregation ratio of the particles of the latent curing agent (B) is reduced, and the epoxy resin composition of the present embodiment tends to be excellent in all of curability, storage stability, and gap permeability.

Examples of a method for obtaining a latent curing agent (B) that is the core-shell type curing agent particle as described above, wherein the shell (s) has a predetermined bonding group (x), bonding group (y), and bonding group (z) as described above include a method involving selecting a predetermined encapsulating agent and reacting the same with the curing agent component of the core.

In addition, the latent curing agent (B) preferably satisfies the relationship represented by the following expression (2) with the specific surface area value (=Y (m²/g)) and the particle diameter D50 at an undersize fraction of 50% (=X (μm)).

$$4. X - 1 \leq Y \leq 8.3 X - 1 \qquad ( 2 )$$

In the following formula (2), X represents a particle diameter D50 (μm) at an undersize fraction of 50% of the latent curing agent (B), and Y represents a specific surface area value (m²/g).

Examples of a method for allowing the specific surface area value and the particle diameter D50 to satisfy the relationship of the above formula (2) include a method involving modifying the surface of the latent curing agent (B).

In addition, when Y is equal to or greater than 4.0X−1, the aggregation of the particles of the latent curing agent (B) can be suppressed, and when Y is equal to or less than 8.3X−1, the stability after mixing the latent curing agent (B) and the epoxy resin (A) can be improved.

When the latent curing agent (B) is a core-shell type curing agent particle having a core of a curing agent component and a shell covering the core, for example, when the latent curing agent (B) is obtained by encapsulating a curing agent component with an encapsulating agent, the curing agent component before encapsulation may satisfy the above formula (2).

The content of the latent curing agent (B) in the epoxy resin composition of the present embodiment can be appropriately set according to the desired performance and is not particularly limited, and is preferably 0.2% by mass or more, more preferably 1.0% by mass or more, and further preferably 2.0% by mass or more from the viewpoint of reactivity. In addition, the content thereof is preferably 50% by mass or less, more preferably 40% by mass or less, and further preferably 30% by mass or less from the viewpoint of stability.

### (Alcohol (C))

The epoxy resin composition of the present embodiment preferably further contains an alcohol (C) represented by the following general formula (1).

By containing the alcohol (C), the epoxy resin composition of the present embodiment tends to have improved reactivity while maintaining the stability.

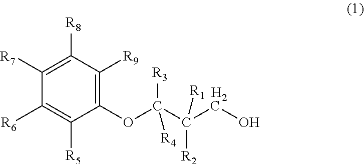

wherein R₁ to R₉ are each independently one selected from the group consisting of a hydrogen atom, a hydroxyl group, an alkyl group, an aromatic group, a substituent including a hetero atom, and a substituent including a halogen atom; R₁ to R₉ are the same or different; and any selected from R₅ to R₉ optionally bonds with each other to form a ring structure, and the ring structure is optionally a ring condensed with a benzene ring shown in the formula.

The alcohol (C) represented by the formula (1) has excellent coordinability to the latent curing agent (B) described above and compatibility with the epoxy resin (A) due to having an aromatic ring and has the function of improving the curability of the epoxy resin composition of the present embodiment.

When the latent curing agent (B) is an amine-based curing agent that is solid at 25° C., the alcohol (C) does not act on the latent curing agent (B) under a room temperature condition. However, under a condition of a predetermined temperature or higher, the alcohol (C) has improved solubility in the epoxy resin (A), the SP value, which is a solubility parameter, is close to that of the latent curing agent (B) that is an amine-based curing agent, and the curability is improved by the action of easily dissolving the latent curing agent (B) in the epoxy resin (A). Because of this, by adding the alcohol (C) in the presence of the latent curing agent (B) that is an amine-based curing agent that is solid at 25° C., both the room temperature stability and the curability at the time of heating of the epoxy resin composition of the present embodiment can be achieved. This effect is more pronounced when the latent curing agent (B) is a capsule type.

In addition, R₁ in formula (1) representing the alcohol (C) is preferably a hydroxyl group from the viewpoint of improving the coordinability to the latent curing agent (B) and further improving the curability of the epoxy resin composition of the present embodiment.

Further, R₂, R₃, and R₄ in the formula (1) are each preferably a hydrogen atom from the viewpoint of not inhibiting the coordinability of the hydroxyl group because of steric hindrance.

Examples of the alcohol (C) represented by the formula (1) include, but are not limited to, 3-phenoxy-1-propanol, 3-phenoxy-1,2-propanediol, 3-phenoxy-1,3-propanediol, mephenesin (3-(2-methylphenoxy-1,2-propanediol), guaifenesin (3-(2-methoxyphenoxy) propane-1,2-diol), bisphenol A (3-hydroxypropyl) glycidyl ether, bisphenol A (2,3-dihydroxypropyl) glycidyl ether, and a compound represented by the following formula (1-1) (hereinafter, also referred to as “compound 1”).

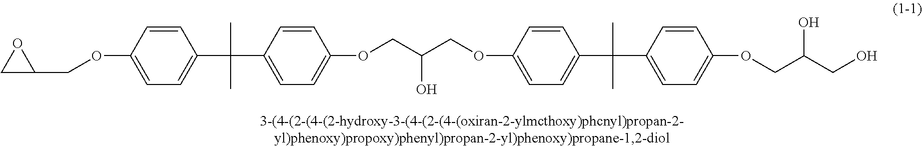 [SMILES: CC(C)(c1ccc(OCC(O)CO)cc1)c1ccc(OCC(O)COc2ccc(C(C)(C)c3ccc(OCC4CO4)cc3)cc2)cc1]

Further examples of the alcohol (C) represented by the formula (1) include a compound having a 1-propanol structure generated by ring-opening a terminal epoxy group of a bisphenol F type epoxy resin, a compound having a 1,2-propanediyl structure generated by ring-opening a terminal epoxy group of a bisphenol F type epoxy resin (for example, bisphenol F glycidyl 2,3-dihydroxypropyl ether), a compound having a 1-propanol structure generated by ring-opening a terminal epoxy group of a naphthalene type epoxy resin, a compound having a 1,2-propanediyl structure generated by ring-opening a terminal epoxy group of a naphthalene type epoxy resin, a compound having a 1-propanol structure generated by ring-opening a terminal epoxy group of a phenol novolac type epoxy resin, a compound having a 1,2-propanediyl structure generated by ring-opening a terminal epoxy group of a phenol novolac type epoxy resin, a compound having a 1-propanol structure generated by ring-opening a terminal epoxy group of a cresol novolac type epoxy resin, and a compound having a 1,2-propanediyl structure generated by ring-opening a terminal epoxy group of a cresol novolac type epoxy resin.

In particular, as the alcohol (C), 3-phenoxy-1-propanol, 3-phenoxy-1,2-propanediol, bisphenol A (3-hydroxypropyl) glycidyl ether, bisphenol A (2,3-dihydroxypropyl) glycidyl ether, and the compound 1 are preferable from the viewpoint of being able to obtain a homogeneous epoxy resin composition because the effect of lowering the thickening start temperature of the epoxy resin composition of the present embodiment is high and the compatibility with the epoxy resin (A) is good.

The content of the alcohol (C) in the epoxy resin composition of the present embodiment can be appropriately set according to the desired performance and is not particularly limited, and is preferably 0.001 parts by mass or more, more preferably 0.005 parts by mass or more, further preferably 0.01 parts by mass or more, and further more preferably 0.1 parts by mass or more per 100 parts by mass in total of the epoxy resin (A) and the latent curing agent (B), from the viewpoint of improving the reactivity.

In addition, the content thereof is preferably 20 parts by mass or less, more preferably 15 parts by mass or less, and further preferably 10 parts by mass or less from the viewpoint of stability and a physical property after curing.

### (Further Curing Agent Component)

The epoxy resin composition of the present embodiment may include one or more curing agents selected from the group consisting of a phenol-based curing agent, an active ester curing agent, an amine-based curing agent, an acid anhydride-based curing agent, and a thiol-based curing agent, as a further curing agent component other than the latent curing agent (B) described above.

### <Phenol-Based Curing Agent>

The phenolic resin-based curing agent is not particularly limited as long as it can cure the epoxy resin (A), and examples thereof include phenol novolac, bisphenol A novolac, cresol novolac, naphthol novolac, and triazine ring-containing phenol novolac.

Triazine ring-containing phenol novolac is preferable as the phenol-based curing agent from the viewpoint of improving the dielectric loss tangent of the epoxy resin composition of the present embodiment. Specific examples thereof include LA3018, LA3018-50P, EXB9808, and EXB9829 (manufactured by DIC Corporation).

### <Active Ester Curing Agent>

The active ester curing agent is not particularly limited as long as it functions as a curing agent for the epoxy resin (A) and has an active ester, and is preferably a compound having two or more active ester groups in one molecule.

The active ester curing agent is more preferably an active ester compound obtained by reacting a carboxylic acid compound and/or a thiocarboxylic acid compound with a hydroxy compound and/or a thiol compound, and further preferably an active ester compound obtained by reacting a carboxylic acid compound with one or more selected from the group consisting of a phenol compound, a naphthol compound, and a thiol compound, from the viewpoint of the heat resistance and the like of the epoxy resin composition of the present embodiment. Moreover, the active ester curing agent is further more preferably an aromatic compound having two or more active ester groups in one molecule obtained by reacting a carboxylic acid compound with an aromatic compound having a phenolic hydroxyl group. Furthermore, the active ester curing agent is more further preferably an aromatic compound obtained by reacting a compound having at least two or more carboxylic acids in one molecule with an aromatic compound having a phenolic hydroxyl group, wherein the aromatic compound has two or more active ester groups in one molecule thereof.

The active ester curing agent may be linear or branched. When the “compound having at least two or more carboxylic acids in one molecule” is a compound including an aliphatic chain, the active ester curing agent obtained by using the “compound having at least two or more carboxylic acids in one molecule” has high compatibility with the epoxy resin (A). In addition, if the active ester curing agent is a compound having an aromatic ring, the heat resistance of the epoxy resin composition of the present embodiment can be increased.

Here, examples of the carboxylic acid compound used for generating the active ester curing agent include, but are not limited to, benzoic acid, acetic acid, succinic acid, maleic acid, itaconic acid, phthalic acid, isophthalic acid, terephthalic acid, and pyromellitic acid. In particular, succinic acid, maleic acid, itaconic acid, phthalic acid, isophthalic acid, and terephthalic acid are preferable, and isophthalic acid and terephthalic acid are more preferable from the viewpoint of the heat resistance of the epoxy resin composition of the present embodiment.

Examples of the thiocarboxylic acid compound used for generating the active ester curing agent include, but are not limited to, thioacetic acid and thiobenzoic acid.

Examples of the phenol compound or the naphthol compound used for generating the active ester curing agent include, but are not limited to, hydroquinone, resorcin, bisphenol A, bisphenol F, bisphenol S, phenolphthalin, methylated bisphenol A, methylated bisphenol F, methylated bisphenol S, phenol, o-cresol, m-cresol, p-cresol, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzenetriol, dicyclopentadienyldiphenol, and phenol novolac. Among these, bisphenol A, bisphenol F, bisphenol S, methylated bisphenol A, methylated bisphenol F, methylated bisphenol S, catechol, α-naphthol, β-naphthol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzenetriol, dicyclopentadienyldiphenol, and phenol novolac are preferable, catechol, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, phloroglucin, benzenetriol, dicyclopentadienyldiphenol, and phenol novolac are more preferable, 1,5-dihydroxynaphthalene, 1,6-dihydroxynaphthalene, 2,6-dihydroxynaphthalene, dihydroxybenzophenone, trihydroxybenzophenone, tetrahydroxybenzophenone, dicyclopentadienyldiphenol, and phenol novolac are further preferable, dihydroxybenzophenone, trihydroxybenzophenone, tetrahydroxybenzophenone, dicyclopentadienyldiphenol, and phenol novolac are further more preferable, dicyclopentadienyldiphenol and phenol novolac are especially preferable, and dicyclopentadienyldiphenol is more further preferable, from the viewpoint of the heat resistance of a cured product obtained from the epoxy resin composition of the present embodiment and the solubility of the active ester curing agent.

Examples of the thiol compound used for generating the active ester curing agent include, but are not limited to, benzenedithiol and triazinedithiol.

As the active ester curing agent, the active ester compound disclosed in Japanese Patent Laid-Open No. 2004-277460 may be used, or a commercially available one can also be used. The commercially available active ester compound is not limited to the following, and for example, a compound including a dicyclopentadienyldiphenol structure, an acetylated product of phenol novolac, and a benzoylated product of phenol novolac are preferable, and particularly a compound including a dicyclopentadienyldiphenol structure is more preferable. Examples of the compound including a dicyclopentadienyldiphenol structure include EXB9451, EXB9460, and EXB9460S (manufactured by DIC Corporation), examples of the acetylated product of phenol novolac include DC808 (manufactured by Mitsubishi Chemical Corporation), and examples of the benzoylated product of phenol novolac include YLH1026 (manufactured by Mitsubishi Chemical Corporation).

### <Amine-Based Curing Agent>

Examples of the amine-based curing agent include, but are not limited to, dicyandiamide, a dicyandiamide derivative such as a dicyandiamide-aniline adduct, a dicyandiamide-methylaniline adduct, a dicyandiamide-diaminodiphenylmethane adduct, or a dicyandiamide-diaminodiphenyl ether adduct, a guanidine salt such as guanidine nitrate, guanidine carbonate, guanidine phosphate, guanidine sulfamate, or aminoguanidine bicarbonate, acetylguanidine, diacetylguanidine, propionylguanidine, dipropionylguanidine, cyanoacetylguanidine, guanidine succinate, diethyl cyanoacetyl guanidine, dicyandiamidine, N-oxymethyl-N′-cyanoguanidine, N,N′-dicarboethoxyguanidine, metaphenylenediamine, paraphenylenediamine, 3,3′-diaminodiphenylsulfone, 4,4′-diaminodiphenylsulfone, 4,4′-diaminodiphenylmethane, and 4,4′-diaminodiphenyl ether.

When the above latent curing agent (B) is an amine-based curing agent having an amine moiety, it can be distinguished from the above amine-based curing agents other than the component (B) depending on whether or not the amine-based curing agent has latency.

### <Acid Anhydride-Based Curing Agent>

Examples of the acid anhydride-based curing agent include, but are not limited to, phthalic anhydride, trimellitic anhydride, pyromellitic anhydride, maleic anhydride, tetrahydrophthalic anhydride, methyltetrahydrophthalic anhydride, methylnadic anhydride, hexahydrophthalic anhydride, and methylhexahydrophthalic anhydride.

### <Thiol-Based Curing Agent>

The thiol-based curing agent is not particularly limited as long as it contains two or more thiol groups in one molecule, and examples thereof include, but are not limited to, 3,3′-dithiodipropionic acid, trimethylpropane tris(thioglycolate), pentaerythritol tetrakis(thioglycolate), ethylene glycol dithioglycolate, 1,4-bis(3-mercaptobutyryloxy) butane, tris [(3-mercaptopropionyloxy)-ethyl]-isocyanurate, 1,3,5-tris(3-mercaptobutyloxyethyl)-1,3,5-triazine-2,4,6 (1H,3H,5H)-trione, trimethylolpropane tris(3-mercaptopropionate), pentaerythritol tetrakis(3-mercaptopropionate), pentaerythritol tetrakis(3-mercaptobutyrate), dipentaerythritol hexakis (3-mercaptopropionate), 1, 3, 4, 6-tetrakis(2-mercaptoethyl) glycoluril, 4-butanedithiol, 1,6-hexanedithiol, and 1,10-decanedithiol. From the viewpoint of the impact resistance of a cured product obtained from the epoxy resin composition of the present embodiment, 1,4-bis(3-mercaptobutyryloxy) butane, 1,3,5-tris(3-mercaptobutyloxyethyl)-1,3,5-triazine-2,4,6 (1H,3H,5H)-trione, pentaerythritol tetrakis(3-mercaptopropionate), pentaerythritol tetrakis(3-mercaptobutyrate) are preferable, and from the viewpoint of the low temperature curability of the epoxy resin composition of the present embodiment, pentaerythritol tetrakis(3-mercaptopropionate) and pentaerythritol tetrakis(3-mercaptobutyrate) are more preferable.

The content of the further curing agent component other than the latent curing agent (B) in the epoxy resin composition of the present embodiment can be appropriately set according to the desired performance and is not particularly limited, and is preferably 0.01% by mass or more, more preferably 0.1% by mass or more, and further preferably 1.0% by mass or more from the viewpoint of reactivity. In addition, the content thereof is preferably 50% by mass or less, more preferably 45% by mass or less, and further preferably 40% by mass or less from the viewpoint of stability.

### (Film-Forming Polymer (D))

The epoxy resin composition of the present embodiment may contain a film-forming polymer (D).

As the film-forming polymer (D), a general polymer that, when the polymer is formed into a film by casting or applying the polymer to a certain thickness followed by drying, has the function of being able to prevent the occurrence of a crack and a split and being able to maintain the film shape can be used.

Examples of the film-forming polymer (D) include, but are not limited to, a phenoxy resin, a polyvinyl butyral resin, a polyvinyl acetal resin, and an elastomer having a functional group such as a carboxyl group, a hydroxyl group, a vinyl group, or an amino group.

Film-forming polymers (D) may be used singly or in combinations of two or more.

As the film-forming polymer (D), a phenoxy resin having excellent long-term connection reliability is preferable. Examples of the phenoxy resin include, but are not limited to, a bisphenol A type phenoxy resin, a bisphenol F type phenoxy resin, a bisphenol A bisphenol F mixed type phenoxy resin, a bisphenol A biphenyl mixed type phenoxy resin, a bisphenol A bisphenol S mixed type phenoxy resin, a fluorene ring-containing phenoxy resin, and a caprolactone modified bisphenol A type phenoxy resin.

The molecular weight of the film-forming polymer (D) is not particularly limited, and the number average molecular weight thereof is preferably 9,000 or more and 23,000 or less, more preferably 9,500 or more and 21,000 or less, and further preferably 10,000 or more and 20,000 or less. Here, the number average molecular weight is a polystyrene-equivalent number average molecular weight obtained by gel permeation chromatography (hereinafter referred to as GPC), and is a value obtained by calculating an average value for a region having a polystyrene-equivalent molecular weight of 728 or more.

A number average molecular weight of the film-forming polymer (D) of 9,000 or more is preferable because such a number average molecular weight can suppress the slip-through of the film-forming polymer (D) from the crosslinked structure of the cured epoxy resin (A) and can suppress a decrease in the cohesive force of the cured product of the epoxy resin composition of the present embodiment, and thus can suppress a decrease in connection reliability between substrates in a printed wiring board and between a printed wiring board and a semiconductor package.

On the other hand, a number average molecular weight of the film-forming polymer (D) of 23,000 or less is preferable because such a number average molecular weight allows an adhesive film using the epoxy resin composition of the present embodiment as a material of the adhesive layer to maintain high close adhesiveness to an adherend such as a predetermined substrate or IC chip, can suppress the occurrence of local poor curing at the time of connection, and makes the occurrence of corrosion of a wiring and an electrode unlikely to allow high insulation reliability to be obtained.

The content of the film-forming polymer (D) in the epoxy resin composition of the present embodiment can be appropriately set according to the desired performance and is not particularly limited, and is preferably 5% by mass or more, more preferably 10% by mass or more, and further preferably 15% by mass or more from the viewpoint of preventing a split after forming the epoxy resin composition of the present embodiment into a film. In addition, the content thereof is preferably 90% by mass or less, more preferably 80% by mass or less, and further preferably 70% by mass or less from the viewpoint of the handleability of a varnish and the ease of manufacture of the film.

By setting the content of the film-forming polymer (D) in the above numerical range, an epoxy resin composition having good storage stability when formed into a film and excellent embeddability and curing performance can be obtained.

### (Filler (E))

The epoxy resin composition of the present embodiment preferably further includes a filler (E).

The filler (E) is not particularly limited, and from the viewpoint of the thermal expansion coefficient and thermal conductivity, examples thereof include an inorganic filler, and an inorganic filler obtained by treating an inorganic filler with a silane coupling agent, and from the viewpoint of improving the adhesive strength and the crack resistance, examples thereof include an organic filler.

Fillers (E) may be used singly or in combinations of two or more. The shape of the filler (E) is not particularly limited, and may be any form of, for example, an indefinite shape, a spherical shape, or a scaly shape.

When the epoxy resin composition of the present embodiment contains an inorganic filler, the thermal expansion coefficient can be adjusted, and the heat resistance and the moisture resistance tend to be improved.

Examples of the inorganic filler include, but are not limited to, a silicate such as talc, calcined clay, uncalcined clay, mica, or glass; an oxide such as titanium oxide, aluminum oxide (alumina), or a silica oxide such as fused silica (fused spherical silica, fused crushed silica), synthetic silica, or crystalline silica; a carbonate such as calcium carbonate, magnesium carbonate, or hydrotalcite; a hydroxide such as aluminum hydroxide, magnesium hydroxide, or calcium hydroxide; a sulfate such as barium sulfate or calcium sulfate; a sulfite such as calcium sulfite; a borate such as zinc borate, barium metaborate, aluminum borate, calcium borate, or sodium borate; and a nitride such as aluminum nitride, boron nitride, or silicon nitride. Among these, from the viewpoint of improving the heat resistance, the moisture resistance, and the strength of a cured product obtained from the epoxy resin composition of the present embodiment, fused silica, crystalline silica, and synthetic silica powder are preferable, and any of silicon oxide, aluminum oxide, and boron nitride is preferable. By using these, the thermal expansion coefficient of a cured product obtained from the epoxy resin composition of the present embodiment can be suppressed, and thus improvement or the like of a thermal cycle test is expected.

When an inorganic filler is used as the filler (E), the content of the inorganic filler in the epoxy resin composition of the present embodiment can be appropriately set according to the desired performance and is not particularly limited, and is preferably 10% by mass or more and 90% by mass or less, and more preferably 20% by mass or more and 85% by mass or less based on the total amount of the epoxy resin composition.

By setting the content of the inorganic filler to 10% by mass or more, an excellent low thermal expansion coefficient tends to be able to be realized. By setting the content of the inorganic filler to 90% by mass or less, the increase in elastic modulus tends to be able to be further suppressed.

The inorganic filler is preferably surface-treated with a silane coupling agent.

The silane coupling agent exerts the performance thereof even when contained in the epoxy resin composition of the present embodiment, but by carrying out surface treatment of an inorganic filler with a silane coupling agent, further reduction in the viscosity of the epoxy resin composition of the present embodiment tends to be able to be realized.

Examples of the silane coupling agent include, but are not limited to, a silane coupling agent such as 3-glycidoxypropyltrimethoxysilane, 3-glycidoxypropylmethyldimethoxysilane, 2-(3,4-epoxycyclohexyl)ethyltrimethoxysilane, N-phenyl-Y-aminopropyltrimethoxysilane, N-(2-aminoethyl) 3-aminopropylmethyldimethoxysilane, N-(2-aminoethyl) 3-aminopropylmethyltrimethoxysilane, 3-aminopropyltriethoxysilane, 3-mercaptopropyltrimethoxysilane, vinyltrimethoxysilane, N-(2-(vinylbenzylamino)ethyl) 3-aminopropyltrimethoxysilane hydrochloride, 3-methacryloxypropyltrimethoxysilane, 3-chloropropylmethyldimethoxysilane, or 3-chloropropyltrimethoxysilane.

Among these, a silane coupling agent having a polymerizable functional group is preferable from the viewpoint of the adhesive strength of the epoxy resin composition of the present embodiment after curing.

The organic filler has a function as an impact relaxation agent having a stress relaxation property in the epoxy resin composition of the present embodiment.

By containing an organic filler, the epoxy resin composition of the present embodiment has further improved adhesiveness to various connection members. In addition, the occurrence and propagation of a crack tends to be able to be suppressed.

Examples of the organic filler include, but are not limited to, an acrylic resin, a silicone resin, butadiene rubber, polyester, polyurethane, polyvinyl butyral, polyarylate, polymethyl methacrylate, acrylic rubber, polystyrene, NBR, SBR, a silicone modified resin, and an organic fine particle of a copolymer including any thereof as a component.

As the organic fine particle, for example, an alkyl (meth)acrylate-butadiene-styrene copolymer, an alkyl (meth)acrylate-silicone copolymer, a silicone-(meth)acrylic copolymer, a composite of silicone and (meth)acrylic acid, a composite of alkyl (meth)acrylate-butadiene-styrene and silicone, and a composite of alkyl (meth)acrylate and silicone are preferable from the viewpoint of improving the adhesiveness.

As the organic filler, an organic fine particle having a core-shell type structure and being different in composition between a core layer and a shell layer can also be used.

Examples of the core-shell type organic fine particle include, but are not limited to, a particle obtained by grafting an acrylic resin on silicone-acrylic rubber as a core, and a particle obtained by grafting an acrylic resin on an acrylic copolymer.

By lowering the elastic modulus by containing a core-shell type organic fine particle, the stress generated in a fillet portion is reduced, and the occurrence of a crack tends to be able to be suppressed. In addition, when a crack occurs, the contained core-shell type organic fine particle acts as a stress relaxation agent and tends to suppress the propagation of the crack.

As a constituent material of the core layer, a material having excellent flexibility is preferably used. Examples of a constituent material of the core layer include, but are not limited to, a silicone-based elastomer, a butadiene-based elastomer, a styrene-based elastomer, an acrylic-based elastomer, a polyolefin-based elastomer, and a silicone/acrylic-based composite-based elastomer.

On the other hand, as a constituent material of the shell layer, a material having excellent affinity for another component of a semiconductor resin encapsulant, particularly excellent affinity for an epoxy resin, is preferable. Examples of the constituent material of the shell layer include, but are not limited to an acrylic resin and an epoxy resin. Among these, an acrylic resin is particularly preferable from the viewpoint of the affinity for another component in the epoxy resin composition of the present embodiment, particularly the affinity for the epoxy resin (A).

When an organic filler is used as the filler (E), the content of the organic filler in the epoxy resin composition of the present embodiment can be appropriately set according to the desired performance and is not particularly limited, and is preferably 1% by mass or more and 20% by mass or less, more preferably 2% by mass or more and 18% by mass or less, and further preferably 3% by mass or more and 16% by mass or less based on the total amount of the epoxy resin composition.

When the content of the organic filler is 1% by mass or more, stress relaxation works, and the effect of improving the adhesion strength of the epoxy resin composition of the present embodiment can be obtained. When the content of the organic filler is 20% by mass or less, the effect of improving the thermal reflow resistance can be obtained in the epoxy resin composition of the present embodiment.

### (Additive (F))

The epoxy resin composition of the present embodiment may further include a further additive (F) other than the alcohol (C), the film-forming polymer (D), and the filler (E) described above.

As the additive (F), for example, a reactive diluent, a solvent, a thermoplastic polymer, a stabilizer, a liquid low stress agent, a flame retardant, and a leveling agent can be used from the viewpoint of, for example, adjusting the viscosity of the epoxy resin composition of the present embodiment.

Additives (F) may be used singly or in combinations of two or more.

The content of the additive (F) can be appropriately set according to the desired performance and is not particularly limited, and is preferably 0.00001% by mass or more, more preferably 0.0001% by mass or more, and further preferably 0.001% by mass or more based on the total amount of the epoxy resin composition of the present embodiment. In addition, the content of the additive (F) is preferably less than 20% by mass, more preferably less than 15% by mass, further preferably less than 10% by mass, and further more preferably less than 8% by mass, more further preferably less than 7% by mass, particularly preferably less than 6% by mass, still more preferably less than 5% by mass, further extremely less than 3% by mass, and particularly extremely less than 2% by mass based on the total amount of the epoxy resin composition of the present embodiment.

### <Reactive Diluent>

The reactive diluent can reduce the viscosity of the epoxy resin composition of the present embodiment and react with the latent curing agent (B) to become a part of a cured product.

As the reactive diluent, a compound containing one or more glycidyl groups in the molecule thereof can be used. Examples of the reactive diluent include, but are not limited to, butyl glycidyl ether, diglycidyl aniline, N,N′-glycidyl-o-toluidine, phenylglycidyl ether, styrene oxide, ethylene glycol diglycidyl ether, propylene glycol diglycidyl ether, and 1,6-hexanediol diglycidyl ether.

In addition, examples thereof include the above-described epoxy resins that can be used as the reactive diluent. That is, examples of the reactive diluent also include various epoxy resins such as 2-ethylhexyl glycidyl ether, cyclohexanedimethanol diglycidyl ether, neopentyl glycol diglycidyl ether, a hydrogenated bisphenol A type epoxy resin, a silicone modified epoxy resin, (poly)ethylene glycol diglycidyl ether, (poly) propylene glycol diglycidyl ether, butanediol diglycidyl ether, trimethylolpropane diglycidyl ether, polytetramethylene ether glycol diglycidyl ether, glycerin diglycidyl ether, neopentyl glycol diglycidyl ether, cyclohexane type diglycidyl ether, dicyclopentadiene type diglycidyl ether, trimethylolpropane triglycidyl ether, glycerin triglycidyl ether, vinyl (3,4-cyclohexene)dioxide, 2-(3,4-epoxycyclohexyl)-5,1-spiro-(3,4-epoxycyclohexyl)-m-dioxane, a glycidylamine type epoxy resin such as tetraglycidyl bis(aminomethyl)cyclohexane, a 1,3-diglycidyl-5-methyl-5-ethylhydantoin type epoxy resin, a 1,3-bis(3-glycidoxypropyl)-1,1,3,3-tetramethyldisiloxane type epoxy resin, phenylglycidyl ether, cresyl glycidyl ether, p-s-butylphenylglycidyl ether, p-tert-butylphenylglycidyl ether, o-phenylphenol glycidyl ether, p-phenylphenol glycidyl ether, N-glycidylphthalimide, n-butylglycidyl ether, 2-ethylhexyl glycidyl ether, α-pinene oxide, allyl glycidyl ether, 1-vinyl-3,4-epoxycyclohexane, 1,2-epoxy-4-(2-methyloxiranyl)-1-methylcyclohexane, 1,3-bis(3-glycidoxypropyl)-1,1,3,3-tetramethyldisiloxane, or neodecanoic acid glycidyl ester.

As the reactive diluent, various monoepoxy compounds and glycidyl ether compounds of polyhydric alcohols can also be used, but these have only one functional group (epoxy group, glycidyl group) that contributes to the reaction with the latent curing agent (B) in one molecule and cannot form a three-dimensional crosslink at the time of curing, and thus tend to be unable to make the glass transition temperature (Tg) or the toughness of a cured product of the epoxy resin composition of the present embodiment sufficient. Therefore, as the reactive diluent, a compound including two or more glycidyl groups in one molecule is preferable because the compound can form a three-dimensional crosslink at the time of curing. This tends to suppress a decrease in glass transition temperature (Tg) or toughness at the time of curing.

Reactive diluents may be used singly or in combinations of two or more.

The content of the reactive diluent in the epoxy resin composition of the present embodiment can be appropriately set according to the desired performance and is not particularly limited, and is preferably 1.0 part by mass or more and 30 parts by mass or less per 100 parts by mass of the epoxy resin (A). When the content of the reactive diluent is 1.0 part by mass or more, the increase in the viscosity of the epoxy resin composition at normal temperature is suppressed, and good embeddability tends to be obtained when the epoxy resin composition of the present embodiment is used as a film for wiring embedding. In addition, the decrease in glass transition temperature (Tg) or toughness at the time of curing of the epoxy resin composition of the present embodiment tends to be suppressed, and the occurrence and propagation of a fillet crack tends to be suppressed.

On the other hand, when the content of the reactive diluent is 30 parts by mass or less per 100 parts by mass of the epoxy resin (A), the decrease in close adhesiveness to an adherend tends to be suppressed, and peeling at the time of a moisture absorption reflow test tends to be suppressed.

In addition, the content of the reactive diluent may be adjusted to a high level for the purpose of suppressing an increase in the viscosity of the epoxy resin composition generated when highly filled with the filler (E).

### <Solvent>

Examples of the solvent include, but are not limited to a halogen-based solvent such as dichloromethane or chloroform; an aromatic solvent such as benzene, toluene, xylene, or mesitylene; and a ketone solvent such as an aliphatic ketone such as acetone, methyl ethyl ketone, methyl isopropyl ketone, methyl isobutyl ketone, or cyclohexanone and an aromatic ketone such as acetophenone.

In addition, a solvent such as ethyl acetate, dimethylformamide, methyl cellosolve, or propylene glycol monomethyl ether can also be used in combination with the above solvent. Among these, ethyl acetate is preferably used as an ester from the viewpoint of the solubility and the boiling point of the epoxy resin composition of the present embodiment.

As the solvent to be combined with ethyl acetate, an aromatic solvent having a boiling point of 120° C. or less, such as toluene, is preferable. Solvents may be used singly or in combinations of two or more.

### <Thermoplastic Polymer>

Examples of the thermoplastic polymer include, but are not limited to, a polyamide resin, polyimide, a polyester resin, a polyurethane resin, an acrylic resin, a carboxylic acid vinyl ester, and a polyether resin. Among these, an acrylic resin is preferable, and a carboxylic acid vinyl ester is more preferable. Thermoplastic polymers may be used singly or in combinations of two or more.

As the acrylic resin, an acrylic resin having a glass transition temperature (Tg) of 25° C. or less is preferable, one or more resins selected from the group consisting of a hydroxy group-containing acrylic resin, a carboxy group-containing acrylic resin, an acid anhydride group-containing acrylic resin, an epoxy group-containing acrylic resin, an isocyanate group-containing acrylic resin, and a urethane group-containing acrylic resin are more preferable, and a phenolic hydroxyl group-containing acrylic resin is further preferable. Here, the “acrylic resin” refers to a resin containing a (meth)acrylate structure, and in such resins, the (meth)acrylate structure may be contained in the main chain or a side chain.

The number average molecular weight (Mn) of the acrylic resin is preferably 10,000 or more and 1,000,000 or less, and more preferably 30,000 or more and 900,000 or less. Here, the number average molecular weight (Mn) of the acrylic resin is a polystyrene-equivalent number average molecular weight measured by using GPC (gel permeation chromatography).

In addition, when the acrylic resin has a functional group, the functional group equivalent is preferably 1000 or more and 50000 or less, and more preferably 2500 or more and 30000 or less.

The carboxylic acid vinyl ester may include a monomer copolymerizable with the carboxylic acid vinyl ester as a monomer unit. Examples of such a monomer include a carboxylic acid allyl ester and a (meth)acrylic acid alkyl ester, and specific examples thereof include allyl acetate, methyl (meth)acrylate, and ethyl (meth)acrylate.

### <Stabilizer>

As the stabilizer, a material that improves storage stability can be used, and examples thereof include, but are not limited to, boric acid and a cyclic boric acid ester compound.

The cyclic boric acid ester compound includes boron in a cyclic structure. As the cyclic boric acid ester compound, 2,2′-oxybis(5,5′-dimethyl-1,3,2-oxaborinane) is preferable.

Stabilizers may be used singly or in combinations of two or more.

### <Liquid Low Stress Agent>

Examples of the liquid low stress agent include, but are not limited to, a polyalkylene glycol and an amine modified product thereof, an organic rubber such as polybutadiene or acrylonitrile; a silicone rubber such as dimethylsiloxane; and a silicone oil.

Liquid low stress agents may be used singly or in combinations of two or more.

The content of the liquid low stress agent is not particularly limited, and is preferably 5.0 parts by mass or more and 40 parts by mass or less, and more preferably 10 parts by mass or more and 20 parts by mass or less based on the mass (100 parts by mass) of the epoxy resin (A).

### <Flame Retardant>

Examples of the flame retardant include, but are not limited to, a bromine-based flame retardant, a phosphorus-based flame retardant, and an inorganic flame retardant.

Examples of the bromine-based flame retardant include, but are not limited to, tetrabromophenol.

Examples of the phosphorus-based flame retardant include, but are not limited to, 9,10-dihydro-9-oxa-10-phosphananthrene-10-oxide and an epoxy derivative thereof, triphenylphosphine and a derivative thereof, a phosphoric acid ester, a condensed phosphoric acid ester, and a phosphazene compound.

Examples of the nitrogen-based flame retardant include, but are not limited to, a guanidine-based flame retardant, a triazine structure-containing phenol, melamine polyphosphate, and isocyanuric acid.

Examples of the inorganic flame-retardant compound include, but are not limited to, magnesium hydroxide and aluminum hydroxide. The inorganic flame-retardant compound is preferably magnesium hydroxide from the viewpoint of heat resistance.

Flame retardants may be used singly or in combinations of two or more.

The content of the flame retardant is not particularly limited, and is preferably 5.0 parts by mass or more and 200 parts by mass or less, and more preferably 10 parts by mass or more and 100 parts by mass or less based on the mass (100 parts by mass) of the epoxy resin (A).

### <Leveling Agent>

Examples of the leveling agent include, but are not limited to, a silicone-based leveling agent and an acrylic-based leveling agent.

Leveling agents may be used singly or in combinations of two or more.

### [Adhesive Film]

The adhesive film of the present embodiment has a support and a resin layer including the epoxy resin composition of the present embodiment on the support.

Examples of the support include, but are not limited to, a polyolefin such as polyethylene, polypropylene, or polyvinyl chloride, a polyester such as polyethylene terephthalate (hereinafter, sometimes abbreviated as “PET”) or polyethylene naphthalate, polycarbonate, polyimide, and further, release paper, and a metal foil such as a copper foil or an aluminum foil, and these may be subjected to a release treatment in addition to a matte treatment or a corona treatment. The thickness of the support is preferably 10 μm or more and 150 μm or less.

The resin layer preferably contains the epoxy resin composition of the present embodiment in an amount of 50% by mass or more and 100% by mass or less from the viewpoint of reliability. The resin layer may contain an electrically conductive particle in addition thereto.

The adhesive film of the present embodiment can be an adhesive film for forming a build-up layer of a printed wiring board or an adhesive film for an insulating layer of a semiconductor chip package.

The printed wiring board of the present embodiment includes a cured product of the adhesive film, and the semiconductor chip package of the present embodiment includes a cured product of the adhesive film.

The semiconductor device of the present embodiment includes the printed wiring board and/or the semiconductor chip package.

### [Method for Producing Epoxy Resin Composition]

The epoxy resin composition of the present embodiment can be produced by mixing an epoxy resin (A), a latent curing agent (B), and if necessary, a further curing agent other than the latent curing agent (B), an alcohol (C), a film-forming polymer (D), a filler (E), an additive (F), or the like as described above. As the mixing method, a method known in the art can be applied. For example, examples thereof include a method involving heating these to about a temperature at which curing does not occur and mixing the same, or a method involving dissolving or dispersing each resin composition in an organic solvent to form a varnish.

### [Method for Manufacturing Adhesive Film]

As a method for producing the adhesive film, for example, an epoxy resin (A), a latent curing agent (B), and if necessary, a further curing agent other than the latent curing agent, alcohol (C), a film-forming polymer (D), a filler (E), an additive (F), or the like are dissolved in a solvent by heating or uniformly dispersed, and then if necessary cooled to 50° C. or less to obtain a varnish of an epoxy resin composition. The solid concentration of the varnish is not particularly limited, and is preferably 30% by mass or more and 80% by mass or less.

Examples of the solvent include, but are not limited to a halogen-based solvent such as dichloromethane or chloroform; an aromatic solvent such as benzene, toluene, xylene, or mesitylene; and a ketone solvent such as an aliphatic ketone such as acetone, methyl ethyl ketone, methyl isopropyl ketone, methyl isobutyl ketone, or cyclohexanone and an aromatic ketone such as acetophenone. In addition, a further solvent such as ethyl acetate, dimethylformamide, methyl cellosolve, or propylene glycol monomethyl ether can also be used in combination. Among these, ethyl acetate is preferably used in combination as a further solvent from the viewpoint of the solubility and the boiling point of the epoxy resin composition of the present embodiment. As the above solvent to be combined with ethyl acetate, an aromatic solvent having a boiling point of 120° C. or less, such as toluene, is preferably used. Solvents may be used singly or in combinations of two or more.

In the production step of the adhesive film of the present embodiment, it is preferable to dissolve the epoxy resin composition of the present embodiment in a mixed solvent including ethyl acetate at room temperature. Dissolving at room temperature as used herein means that a solution state can be obtained at room temperature when mixing is carried out at a solid concentration of 10% by mass, and refers to a condition wherein a state in which there is substantially no solid is kept for one day or more and preferably for 30 days or more.

The adhesive film of the present embodiment can be produced by applying the above varnish of the epoxy resin composition onto a support film and heating and drying the varnish to remove the solvent to form a film. Thereby, a semi-cured adhesive film can be obtained. As described above, the thickness of the adhesive film after heating and drying is preferably 5 μm or more and 200 μm or less, more preferably 5 μm or more and 120 μm or less, further preferably 7 μm or more and 70 μm or less, and further more preferably 10 μm or more and 20 μm or less.

The thickness of the adhesive film of the present embodiment is preferably 200 μm or less from the viewpoint of being able to make a member used smaller. The thickness thereof is more preferably 120 μm or less, further preferably 70 μm or less, and further preferably 20 μm or less. In addition, the thickness thereof is preferably 5 μm or more from the viewpoint of ensuring the embeddability and the insulating property. The thickness thereof is more preferably 7 μm or more, and further preferably 10 μm or more.

As the heating and drying conditions, the heating temperature is 60° C. or more and 150° C. or less, and preferably 90° C. or more and 120° C. or less, and the heating time is 1 minute or more and 20 minutes or less, and preferably 2 minutes or more and 10 minutes or less.

When the heating and drying conditions are within these ranges, the solvent remaining in the resulting adhesive film is sufficiently removed, and the volatile content in the adhesive film can be reduced to 1% by mass or less. In addition, the curing of the adhesive film due to the film formation can be suppressed, and when the adhesive film of the present embodiment is laminated on a predetermined inner layer circuit board and used, the embeddability between wirings can be ensured.

In the production step of the adhesive film, a known method can be applied as a method for applying the varnish containing the epoxy resin composition of the present embodiment to a support, and the method is not particularly limited, and examples thereof include a bar coater, a lip coater, a die coater, a roll coater, and a doctor blade coater.

### [Printed Wiring Board]

The printed wiring board of the present embodiment includes a layer obtained by curing the above adhesive film of the present embodiment. When a printed wiring board is produced by using an adhesive film, the adhesive film produced by the above method is bonded to a patterned inner layer circuit board, and laminated while being pressurized and heated from the support side. The surface of the inner layer circuit may be subjected to a roughening treatment in advance. The lamination is carried out under normal pressure or reduced pressure in a batch system or a continuous system using a roll, and the lamination is preferably carried out on both sides at the same time. The lamination conditions at this time are preferably such that the pressure bonding temperature is in the range of 70° C. to 150° C. and the pressure bonding pressure is in the range of 0.1 to 60 MPa. In addition, the lamination is preferably carried out under a reduced pressure of 2 KPa or less from the viewpoint of void reduction. The pressure bonding pressure is preferably 40 MPa or less from the viewpoint of maintaining the thickness of the adhesive film after pressure bonding.

After lamination, the laminate is cooled to room temperature, the support is peeled off from the adhesive film, and then the resin layer laminated on the inner circuit board is heat-cured. The curing conditions are preferably such that the curing temperature is within the range of 130 to 250° C. and the curing time is within the range of 30 minutes to 180 minutes.

Next, a part to be a via hole is formed by using a laser such as a carbon dioxide gas laser, and then a roughening treatment is carried out by using an oxidizing agent such as a permanganate, a dichromate, or ozone for the purpose of removing a smear and improving the close adhesiveness to plating. After that, a conductor circuit is selectively formed on the resin layer of an edge layer by electroless plating or electrolytic plating, and at the same time, a conductor layer on the inner wall of the via hole is formed to form an outer layer circuit. After that, the close adhesiveness between the conductor layer and the resin layer can be improved by carrying out an annealing treatment at a temperature in the range of 150 to 250° C. for a period of time in the range of 30 minutes to 60 minutes. A multilayer printed wiring board can be produced by further forming a multi-stage build-up layer by repeating the above production method by using the adhesive film of the present embodiment on the conductor circuit layer thus obtained.

The heat curing is preferably carried out under a condition of 220° C. or less from the viewpoint of volatilizing the organic compound and suppressing degradation.

### [Semiconductor Chip Package and Semiconductor Device]

The semiconductor chip package of the present embodiment includes a cured product of the adhesive film.

The semiconductor device of the present embodiment includes the printed wiring board and/or the semiconductor chip package.

### [Method for Using Adhesive Film]

As described in the above [Printed wiring board], the adhesive film of the present embodiment is preferably laminated under a condition of a pressure bonding pressure of 40 MPa or less, and then heat-cured under a heating condition of a temperature of 220° C. or less to manufacture a predetermined laminated material or semiconductor chip package.

The pressure bonding pressure is more preferably 20 MPa or less, and further preferably 10 MPa or less.

The heat curing temperature is more preferably 200° C. or less, and further preferably 180° C. or less.

By setting the pressure bonding pressure to 40 MPa or less, a practically sufficient thickness can be ensured after pressure bonding.

In addition, by setting the heat curing temperature to 220° C. or less, the organic compound can be sufficiently volatilized, and further, the degradation of the resin layer of the adhesive film can be prevented.

### EXAMPLES

Hereinafter, the present embodiment will be described in more detail with reference to Examples and Comparative Examples, but these are illustrative, and the present invention is not limited by the following Examples and Comparative Examples. That is, those skilled in the art can practice the present invention by making various modifications to the Examples shown below.

Hereinafter, unless otherwise specified, “part (s)” means part (s) by mass.

In addition, the values of various production conditions and evaluation results in the following Examples have meanings as preferable values of the upper limits or the lower limits in the embodiment of the present invention. A preferable range has a meaning as a preferable value of the upper limit or the lower limit described above, and the preferable range may be a range defined by a combination of the value of the upper limit or the lower limit described above and either a value in any of the following Examples or values in the Examples.

### [Production of Constituent Materials of Epoxy Resin Composition]

Hereinafter, Production Examples of constituent materials used in the epoxy resin compositions of the Examples and the Comparative Examples described later will be shown.

### (Production Example 1) Production of Curing Agent 1 for Epoxy Resin

1 Equivalent of a bisphenol A type epoxy resin (manufactured by Mitsubishi Chemical Corporation: trade name “jER828EL”) and 1 equivalent (in terms of active hydrogen) of 2-ethyl-4-methylimidazole were reacted with each other at 80° C. in a 1:1 mixed solvent of n-butanol and toluene. After that, the excess amine was distilled off together with the solvent under reduced pressure to obtain a block-shaped curing agent for an epoxy resin, which was solid at 25° C.

Next, the block-shaped epoxy resin curing agent was pulverized by using a jet mill, and further, a classification operation was carried out by using a classifier to obtain curing agent 1 for an epoxy resin, which was a curing agent for an epoxy resin having a specific surface area value of 3.63 m²/g, an undersize average particle diameter D50 of 2.50 μm, and a distribution with a D99/D50 of 5.4.

### (Production Example 2) Production of Encapsulated Curing Agent 2 for Epoxy Resin

100 Parts by mass of the curing agent 1 for an epoxy resin was uniformly dispersed in 200 parts by mass of hexane, 30 parts by mass of an encapsulating agent (manufactured by Tosoh Corporation: trade name “MR-400”) was added, and the reaction was carried out for 3 hours with stirring at 50° C. to obtain encapsulated curing agent 2 for an epoxy resin, which was solid at 25° C.

An IR measurement of obtained curing agent 2 for an epoxy resin was carried out, and in the shell, peaks due to a bonding group (x) absorbing an infrared radiation having a wave number of 1630 cm⁻¹ or more and 1680 cm⁻¹ or less, a bonding group (y) absorbing an infrared radiation having a wave number of 1680 cm⁻¹ or more and 1725 cm⁻¹ or less, and a bonding group (z) absorbing an infrared radiation having a wave number of 1730 cm⁻¹ or more and 1755 cm⁻¹ or less were observed.

### (Production Example 3) Production of Curing Agent 3 for Epoxy Resin

By using curing agent 1 for an epoxy resin obtained in (Production Example 1), a shape correction treatment was carried out by using KRYPTRON Orb manufactured by EARTHTECHNICA Co., Ltd. at a rotation speed of 13500 rpm, a supply rate of 10 kg/hr, and an air flow rate of 3 m³/min in an environment of a temperature of 10° C. and a humidity of 30%. A cyclone type collector and a bag filter were attached to a classifier, and a classification operation was carried out to obtain curing agent 3 for epoxy resin, which was a curing agent for an epoxy resin having a specific surface area value of 2.67 m²/g, a D50 of 3.1 μm, and a particle size distribution with a D99/D50 of 4.5.

### (Production Example 4) Production of Encapsulated Curing Agent 4 for Epoxy Resin

100 Parts by mass of the curing agent 3 for an epoxy resin was uniformly dispersed in 200 parts by mass of hexane, 20 parts by mass of an encapsulating agent (manufactured by Tosoh Corporation: trade name “Coronate T100”) was added, and the reaction was continued for 3 hours with stirring at 50° C. to obtain encapsulated curing agent 4 for an epoxy resin, which was solid at 25° C.

An IR measurement of obtained curing agent 4 for an epoxy resin was carried out, and in the shell, peaks due to a bonding group (x) absorbing an infrared radiation having a wave number of 1630 cm⁻¹ or more and 1680 cm⁻¹ or less, a bonding group (y) absorbing an infrared radiation having a wave number of 1680 cm⁻¹ or more and 1725 cm⁻¹ or less, and a bonding group (z) absorbing an infrared radiation having a wave number of 1730 cm⁻¹ or more and 1755 cm⁻¹ or less were observed.

### (Production Example 5) Production of Curing Agent 5 for Epoxy Resin

1 Equivalent of a bisphenol A type epoxy resin (manufactured by Mitsubishi Chemical Corporation: trade name “jER828EL”) and 1 equivalent (in terms of active hydrogen) of 2-methylimidazole were reacted with each other at 80° C. in a 1:1 mixed solvent of n-butanol and toluene. After that, the excess imidazole was distilled off together with the solvent under reduced pressure to obtain a block-shaped curing agent for an epoxy resin, which was solid at 25° C. The obtained curing agent for epoxy resin was pulverized by using a turbo mill to obtain curing agent 5 for an epoxy resin having a specific surface area value of 0.36 m²/g, an undersize average particle diameter D50 of 9.80 μm, and a D99/D50 of 4.2.

### (Production Example 6) Production of Polymer D-1 for Film Formation

170 Parts by mass of a biphenyl type epoxy resin (manufactured by Mitsubishi Chemical Corporation: trade name “YX4000”), 110 parts by mass of biphenol, 30 parts by mass of xylene, and 0.05 parts by mass of triethylamine were mixed, and the reaction was carried out at 170° C. for 2 hours with stirring in a nitrogen atmosphere. After completion of the reaction, the temperature was raised to 200° C. over 3 hours while removing xylene out of the system, and the reaction was continued at 200° C. for another 7 hours to obtain a film-forming polymer D-1 having a number average molecular weight of 22,500.

### (Production Example 7) Production of Alcohol C-1

50 Parts by mass of a bisphenol A diglycidyl ether (BADGE, Aldrich reagent, epoxy equivalent of 172 g/eq), 10 parts by mass of methanol, 1 part by mass of water, and 0.005 parts by mass of trimethylammonium chloride were mixed, and the reaction was carried out at 60° C. for 2 hours with stirring in a nitrogen atmosphere.

After completion of the reaction, methanol and the remaining water were distilled off at 140° C. under reduced pressure to obtain an alcohol C-1 having an alcoholic hydroxyl group equivalent of about 20000 g/eq.

### [Methods for Evaluating Properties]

Hereinafter, methods for evaluating the properties of the resin compositions of the Examples and the Comparative Examples described later will be shown.

### ((1) Evaluation of Film Storage Stability)

A 50% MEK (methyl ethyl ketone) solution of the epoxy resin composition of each of the Examples and the Comparative Examples was manufactured and used as a varnish. Immediately after preparing the varnish, the varnish was applied onto a PET film to a thickness of about 50 μm by using a coating machine, and then dried in an oven at 100° C. for 5 minutes to obtain an adhesive film.

An FT-IR measurement of the obtained adhesive film was carried out, and the peak ratio F1 (P1/P2) of the peak at 926 cm⁻¹ derived from an epoxy group (P1) to the peak at 1510 cm⁻¹ derived from a phenyl group (P2) was calculated.

Further, after this adhesive film was stored at 9° C. for 30 days, an FT-IR measurement thereof was carried out by the same method, and the peak ratio F2 (P1/P2) after storage was calculated.

In order to compare the F1 and the F2, the residual amount of the peak ratio of the epoxy group ((F2/F1)×100) was calculated. If the residual amount of the peak ratio of the epoxy group is 90% or more and 99% or more, a rating “⊚” was given; if the residual amount was 70% or more and less than 90%, a rating “◯” was given; if the residual amount was 50% or more and less than 70%, a rating “Δ” was given; and if the residual amount is less than 50%, a rating “X” was given.

### ((2) Evaluation of Embeddability)

The adhesive film manufactured in (1) above was laminated in the state of being attached to a PET film by using a roll-type laminator under conditions of a pressure bonding temperature of 90° C., a pressure bonding pressure of 0.3 to 0.5 MPa, and a lamination rate of 0.4 m/min, on one side of an FR-5 substrate (17 cm×34 cm, thickness of 0.4 mm) provided with wiring lines having a line/space of wirings depicted by a direct imaging treatment using a dry film resist of 10 μm/10 μm and a wiring thickness of 7 μm.

A gap between the wirings where no resin was contained was considered to be a bubble, the presence of a bubble was visually inspected, when no bubble was present, a rating “◯” was given, and when a bubble was present, a rating “X” was given.

### ((3) Evaluation of Warpage)

After lamination in the test in ((2) Embeddability) above, the PET film was peeled off from the adhesive film, and the adhesive film was further pressure-bonded and cured at 175° C. for 45 minutes at 40 MPa to obtain a test piece. After curing, the test piece was placed with a protruding side facing downward at room temperature, and when one 17 cm side of the test piece was pressed against a desk, the height at which the other side rose from the desk was measured.

At this time, when the height from the desk was less than 1.0 cm, a rating “⊚” was given, when the height was 1.0 cm or more and less than 1.5 cm, a rating “◯” was given, when the height was 1.5 or more and less than 3 cm, a rating “Δ” was given, and when the height was 3 cm or more, a rating “X” was given.

### ((4) Evaluation of Heat Resistance)

In the test piece manufactured in ((3) Warpage) above, a portion where no bubble was present was cut into a size of 0.5 cm×0.5 cm, and the resulting workpiece was heated at a constant temperature of 288° C., and the time taken for swelling to occur was measured, by using a measuring instrument TMA Q400 (manufactured by TA Instrumental).

When the time taken for swelling to occur was 60 minutes or more, a rating “◯” was given, when the time was 45 minutes or more and less than 60 minutes, a rating “Δ” was given, and when the time was 45 minutes or less, a rating “X” was given.

### ((5) Evaluation of Peel Strength)

The film-like adhesive from which the PET film was peeled off was sandwiched between an FR-5 substrate and a copper foil having a foil thickness of ½ oz, and pressure-bonded at 165° C. for 30 minutes at 40 MPa. Next, a cut was made in a portion having a width of 10 mm and a length of 150 mm of the copper foil on the substrate, and a 90-degree peel strength measurement was carried out.

When the peel strength was 1.0 kgf/cm or more, a rating “⊚” was given, when the peel strength was 0.8 or more and less than 1.0 kgf/cm, a rating “◯” was given, when the peel strength was 0.6 or more and less than 0.8, a rating “Δ” was given, when the peel strength was 0.4 or more and less than 0.6, a rating “X” was given, and when the peel strength was less than 0.4, a rating “XX” was given.

### ((6) Measurement of Permittivity and Dielectric Loss Tangent)

Forty film-like adhesives from which the PET film was peeled off were stacked and cured at 180° C. for 60 minutes under reduced pressure to obtain a cured product.

The obtained cured product was cut into a width of 2 mm and a length of 80 mm to obtain a test piece. The permittivity (ε) and the dielectric tangent (tanδ) of this test piece were measured by a cavity resonance method at a measurement frequency of 1.0 GHz by using a cavity resonator perturbation method permittivity measuring apparatus manufactured by Kanto Electronic Application and Development Inc. and Network Analyzer E8632B manufactured by Agilent Technologies, Inc.

The permittivity and the dielectric tangent of 5 test pieces were measured, and the average values thereof were calculated; and when the value of √ε×tanδ was less than 0.01, a rating “⊚” was given, when the value was 0.01 or more and less than 0.012, a rating “◯” was given, and when the value was 0.012 or more and less than 0.015, a rating “Δ” was given, and when the value was 0.015 or more, a rating “X” was given.

### Examples 1 to 10 and Comparative Examples 1 and 2

A component (A), a component (B), a component (D), a further curing agent component, a filler (E), and an additive (F) were dissolved or uniformly dispersed in a solvent heated to 60° C. at the blending proportions shown in Table 1 and Table 2, then this was cooled to 30° C., and further, a component (C) was mixed and uniformly dispersed to obtain an epoxy resin composition.

In addition, the epoxy resin composition was applied onto a PET film to a thickness of about 50 μm by using a die coater, and then dried in an oven at 100° C. for 5 minutes to manufacture an adhesive film used for the above evaluations.

### [Constituent Materials of Epoxy Resin Composition]

The components shown in Tables 1 and 2 below are shown below.

### (Epoxy Resins (A))

A-1: EPICLON 850CRP (bisphenol A type epoxy resin, manufactured by DIC Corporation, epoxy equivalent of 175 g/eq)
A-2: YX4000 (biphenyl type epoxy resin, manufactured by Mitsubishi Chemical Corporation, epoxy equivalent of 170 g/eq)
A-3: NC3000H (biphenyl aralkyl type epoxy resin, manufactured by Nippon Kayaku Co., Ltd., epoxy equivalent of 269 g/eq)
A-4: HP4710 (naphthalene type epoxy resin, manufactured by DIC Corporation, epoxy equivalent of 170 g/eq)
A-5: YX7760 (fluorine-containing epoxy resin, manufactured by Mitsubishi Chemical Corporation, epoxy equivalent of 235 g/eq)

### (Components (B))

B-1: Curing agent 1 for epoxy resin of Production Example
B-2: Curing agent 2 for epoxy resin of Production Example 2
B-3: Curing agent 3 for epoxy resin of Production Example 3
B-4: Curing agent 4 for epoxy resin of Production Example 4
B-5: Curing agent 5 for epoxy resin of Production Example 5

### (Further Curing Agent Components)

DMAP: 4-Dimethylaminopyridine (manufactured by Koei Chemical Co., Ltd., water content of 1.7%, specific surface area value of 0.1 m²/g, undersize average particle diameter D50 of 15.4 μm, D99/D50 of 6.4)
LA7054: (Phenol novolac type resin, manufactured by DIC Corporation, hydroxyl group equivalent of 125 g/eq)
LA3018: (Phenol novolac type resin, manufactured by DIC Corporation, hydroxyl group equivalent of 150 g/eq)
EXB9460S: (Active ester resin, manufactured by DIC Corporation, ester equivalent of 223 g/eq)
HPC8000: (Active ester resin, manufactured by DIC Corporation, ester equivalent of 223 g/eq)

### (Components (C))

C-1: Alcohol of Production Example 7
C-2: 3-Phenoxy-1-propanol (reagent, manufactured by Tokyo Chemical Industry Co., Ltd.)
C-3: 3-Phenoxy-1,2-propanediol (reagent, manufactured by Tokyo Chemical Industry Co., Ltd.)

### (Film-Forming Polymers (D))

D-1: Film-forming polymer of Production Example 6
D-2: YP50 (phenoxy resin (manufactured by NIPPON STEEL Chemical & Material Co., Ltd.))

### (Component (E))

E-1: Aminosilane-treated synthetic spherical silica SO-C2 (manufactured by Admatechs Co., Ltd.)

### (Components (F))

F-1: YED216L (1,6-hexanediol diglycidyl ether, manufactured by Mitsubishi Chemical Corporation)
F-2: CDMDG (1,4-cyclohexanedimethanol diglycidyl ether, manufactured by Showa Denko K.K.)

TABLE 1

| | | Exam- | Exam- | Exam- | Exam- | Exam- | Exam- | Exam- | Exam- | Exam- | Exam- |
|---|---|---|---|---|---|---|---|---|---|---|---|
| | | ple 1 | ple 2 | ple 3 | ple 4 | ple 5 | ple 6 | ple 7 | ple 8 | ple 9 | ple 10 |
| A-1 | Parts by mass | | 5 | 5 | | 8 | 15 | 5 | 5 | 5 | 5 |
| A-2 | Parts by mass | 15 | 10 | 5 | 20 | 7 | | 10 | 10 | 5 | 5 |
| A-3 | Parts by mass | 10 | 15 | 10 | | 10 | 5 | | | 5 | 5 |
| A-4 | Parts by mass | 5 | | 5 | 5 | 5 | 10 | | | | |
| A-5 | Parts by mass | | | | | | | 15 | 15 | 10 | 10 |
| B-1 | Parts by mass | 4 | | | | | | | | | |
| B-2 | Parts by mass | | 5 | | | | 5 | | | | |
| B-3 | Parts by mass | | | 4 | | | | | | | |
| B-4 | Parts by mass | | | | 5 | | | 3 | 3 | 3 | 3 |
| B-5 | Parts by mass | | | | | 10 | | | | | |
| DMAP | Parts by mass | | | | | | | | | | |
| LA7054 | Parts by mass | 20 | | 7 | | 10 | | | | | |
| LA3018 | Parts by mass | | 6 | | 6 | | 6 | 10 | 10 | 6 | 6 |
| EXB9460S | Parts by mass | | 20 | | 20 | | 20 | 20 | 20 | | |
| HPC8000 | Parts by mass | | | 20 | | | | | | 20 | 20 |
| C-1 | Parts by mass | 1 | 1 | | 1 | | | | | | |
| C-2 | Parts by mass | | | 1 | | 1 | | | | | 12 |
| C-3 | Parts by mass | | | | | | | 0.001 | 0.0005 | 10 | |
| D-1 | Parts by mass | 10 | 10 | | 10 | | | | | | |
| D-2 | Parts by mass | | | 10 | | 10 | 10 | 20 | 20 | 20 | 20 |
| E-1 | Parts by mass | 90 | 90 | 120 | 130 | 120 | 90 | 140 | 140 | 120 | 120 |
| F-1 | Parts by mass | | | 5 | 6 | | | | | 5 | 5 |
| F-2 | Parts by mass | | | | | | | 5 | 5 | | |
| Total | | 155.0 | 162.0 | 192.0 | 203.0 | 181.0 | 161.0 | 228.0 | 228.0 | 209.0 | 211.0 |
| Film storage stability | | Δ | ◯ | ◯ | ⊚ | Δ | ⊚ | ⊚ | ⊚ | ⊚ | ⊚ |
| Embeddability | | ◯ | ◯ | ◯ | ◯ | ◯ | ◯ | ◯ | ◯ | ◯ | ◯ |
| Warpage | | Δ | ◯ | ◯ | ⊚ | ◯ | ◯ | ⊚ | ⊚ | ⊚ | ⊚ |
| Heat resistance | | ◯ | Δ | Δ | ◯ | Δ | Δ | ◯ | ◯ | Δ | X |
| Peel strength | | ◯ | ◯ | ⊚ | ⊚ | ⊚ | X | Δ | X | Δ | Δ |
| Permittivity | | 3.6 | 3.7 | 3.6 | 3.5 | 3.6 | 3.7 | 3.3 | 3.3 | 3.8 | 3.7 |
| Dielectric loss tangent | | 0.007 | 0.006 | 0.005 | 0.0045 | 0.007 | 0.006 | 0.004 | 0.004 | 0.007 | 0.008 |
| √ε × tan δ | | Δ | ◯ | ⊚ | ⊚ | Δ | ◯ | ⊚ | ⊚ | Δ | X |

TABLE 2

| | | Comparative | Comparative |
|---|---|---|---|
| | | Example 1 | Example 2 |
| A-1 | Parts by mass | | |
| A-2 | Parts by mass | 10 | |
| A-3 | Parts by mass | 20 | 20 |
| A-4 | Parts by mass | | 10 |
| A-5 | Parts by mass | | |
| B-1 | Parts by mass | | |
| B-2 | Parts by mass | | |
| B-3 | Parts by mass | | |
| B-4 | Parts by mass | | |
| B-5 | Parts by mass | | |
| DMAP | Parts by mass | 1 | |
| LA7054 | Parts by mass | | |
| LA3018 | Parts by mass | 8 | 7 |
| EXB9460S | Parts by mass | 15 | 20 |
| HPC8000 | Parts by mass | | |
| C-1 | Parts by mass | | |
| C-2 | Parts by mass | | |
| C-3 | Parts by mass | | |
| D-1 | Parts by mass | 10 | |
| D-2 | Parts by mass | | 10 |
| E-1 | Parts by mass | 70 | 90 |
| F-1 | Parts by mass | | |
| F-2 | Parts by mass | | |
| Total | | 134.0 | 157.0 |
| Film storage stability | | X | ⊚ |
| Embeddability | | X | X |
| Warpage | | Δ | ◯ |
| Heat resistance | | Δ | X |
| Peel strength | | X | XX |
| Permittivity | | 3.5 | 3.7 |
| Dielectric loss tangent | | 0.009 | 0.009 |
| √ε × tan δ | | X | X |

As shown in Table 1 and Table 2, in each of Examples 1 to 10, an epoxy resin composition having good storage stability after film formation, excellent embeddability of a fine wiring and excellent curing performance, and capable of achieving both storage stability and reactivity was obtained.

The present application is based on a Japanese patent application filed with the Japan Patent Office on Dec. 22, 2020 (Japanese Patent Application No. 2020-212769), and a Japanese patent application filed with the Japan Patent Office on Jan. 18, 2021 (Japanese Patent Application No. 2021-005649), the contents of which are incorporated herein by reference.

### INDUSTRIAL APPLICABILITY

The epoxy resin composition of the present embodiment has industrial applicability in the fields of an adhesive film, a printed wiring board, a semiconductor chip package, a semiconductor device, and the like, which are required to have multi-layering, finer and higher density wiring, a lower dielectric loss tangent, or the like.

1. An epoxy resin composition comprising:
an epoxy resin (A); and
a latent curing agent (B), wherein
the latent curing agent (B) is solid at 25° C.

2. The epoxy resin composition according to claim 1, wherein
the epoxy resin composition further comprises an alcohol (C) represented by the following formula (1): 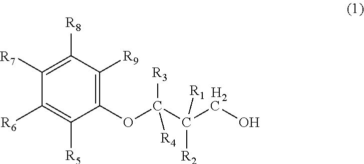
wherein R₁ to R₉ are each independently one selected from the group consisting of a hydrogen atom, a hydroxyl group, an alkyl group, an aromatic group, a substituent including a hetero atom, and a substituent including a halogen atom; R₁ to R₉ are the same or different; and any selected from R₅ to R₉ optionally bonds with each other to form a ring structure, and the ring structure is optionally a ring condensed with a benzene ring shown in the formula.

3. The epoxy resin composition according to claim 1, wherein the latent curing agent (B) is an amine-based curing agent having an amine moiety.

4. The epoxy resin composition according to claim 1, wherein
the latent curing agent (B) has a particle diameter D50 at an undersize fraction of 50% of more than 0.3 μm and 10 μm or less, and
a particle size distribution represented by a ratio (D99/D50) of a particle diameter D99 at an undersize fraction of 99% to the particle diameter D50 at the undersize fraction of 50% of 6 or less.

5. The epoxy resin composition according to claim 1, wherein
the latent curing agent (B) satisfies a relationship represented by the following expression (2) with a specific surface area value (=Y (m²/g)) and the particle diameter D50 at the undersize fraction of 50%(=X (μm)):
$$4. {X}^{- 1} \leq Y \leq 8.3 {X}^{- 1} \qquad ( 2 )$$
wherein when the latent curing agent (B) is obtained by encapsulating a curing agent component with an encapsulating agent, the curing agent component before encapsulation satisfies the above expression (2).

6. The epoxy resin composition according to claim 1, wherein
the latent curing agent (B) comprises
a core (c) that is a curing agent component and a shell (s) covering the core (c), and wherein the shell (s) comprises at least a bonding group (x) absorbing an infrared radiation having a wave number of 1630 cm⁻¹ or more and 1680 cm⁻¹ or less, a bonding group (y) absorbing an infrared radiation having a wave number of 1680 cm⁻¹ or more and 1725 cm⁻¹ or less, and a bonding group (z) absorbing an infrared radiation having a wave number of 1730 cm⁻¹ or more and 1755 cm⁻¹ or less.

7. The epoxy resin composition according to claim 2, wherein
R₁ in the formula (1) is a hydroxyl group.

8. The epoxy resin composition according to claim 2, wherein
the epoxy resin composition comprises the alcohol (C)
in an amount of 0.001 parts by mass or more and 20 parts by mass or less per 100 parts by mass in total of the epoxy resin (A) and the latent curing agent (B).

9. The epoxy resin composition according to claim 2, wherein
the epoxy resin composition comprises the alcohol (C)
in an amount of 0.1 parts by mass or more and 20 parts by mass or less per 100 parts by mass in total of the epoxy resin (A) and the latent curing agent (B).

10. The epoxy resin composition according to claim 1, wherein
the epoxy resin composition further comprises one or more curing agents selected from the group consisting of a phenol-based curing agent, an active ester curing agent, an amine-based curing agent, an acid anhydride-based curing agent, and a thiol-based curing agent, other than the latent curing agent (B).

11. The epoxy resin composition according to claim 1, wherein
the epoxy resin composition further comprises a film-forming polymer (D).

12. The epoxy resin composition according to claim 1, wherein
the epoxy resin composition further comprises a filler (E).

13. The epoxy resin composition according to claim 1, wherein
the filler (E) is an inorganic filler.

14. The epoxy resin composition according to claim 1, wherein
the epoxy resin composition further comprises an additive (F).

15. An adhesive film comprising:
a support; and
a resin layer comprising the epoxy resin composition according to claim 1 on the support.

16. The adhesive film according to claim 15, wherein
the adhesive film has a thickness of 20 μm or less.

17. The adhesive film according to claim 15, wherein
the adhesive film is an adhesive film for forming a build-up layer of a printed wiring board.

18. The adhesive film according to claim 15, wherein
the adhesive film is an adhesive film for an insulating layer of a semiconductor chip package.

19. A printed wiring board comprising a layer obtained by curing the adhesive film according to claim 15.

20. A semiconductor chip package comprising a layer obtained by curing the adhesive film according to claim 15.

21. A semiconductor device comprising the printed wiring board according to claim 19.

22. A method for using the adhesive film according to claim 15, comprising:
laminating the adhesive film under a condition of a pressure bonding pressure of 40 MPa or less and then producing a laminated material or a semiconductor chip package under a heating condition of a temperature of 220° C. or less.

23. A semiconductor device comprising the semiconductor chip package according to claim 20.
